(19) United States
(12) Patent Application Publication
(10) Pub. No.: US 2025/0232087 A1
(43) Pub. Date: Jul. 17, 2025

(54) SHADOW-BASED COMPONENT FINITE ELEMENT ANALYSIS

(71) Applicant: Intergraph Corporation, Madison, AL (US)

(72) Inventor: Ravindra Ozarker, San Jose, CA (US)

(21) Appl. No.: 18/414,274

(22) Filed: Jan. 16, 2024

(51) Int. Cl. G06F 30/23; G06T 15/60

(52) U.S. Cl. CPC G06F 30/23; G06T 15/60

(57) ABSTRACT

Illustrative embodiments operate in a computer-aided design environment to facilitate finite element analysis of a multi-component system, which system includes a master element coupled to a dependent element. Illustrative embodiments cast a shadow of an end of the dependent element, and derive mesh node points on the surface of the master component from the shadow. Illustrative embodiments then form a mesh from the mesh node points, which mesh is input to a finite element analysis engine.

### FIELD

Illustrative embodiments of the invention generally relate to computer-aided design of physical systems and, more particularly, various embodiments relate to finite element analysis of physical systems.

### BACKGROUND

Finite element analysis (“FEA”) is a computer-implemented process of analyzing a physical object using models and simulations to assess how the object will behave under various physical conditions.

For example, an engineer designing a new (i.e., as-yet unbuilt) structure typically performs finite element analysis on a model of the structure prior to finalizing the design, to determine whether the design is structurally sound.

For a pre-existing structure, engineers may want to perform finite element analysis and quickly perform a rough qualification. Performing finite element analysis on a pre-existing structure is more difficult than on an un-built structure being designed, in that the pre-existing structure may have been designed by an older generation of engineers using older design codes and philosophies, and may be made more difficult if accurate and up-to-date models of the pre-existing structure are not available. Typically, the engineer must first create one or more models of the existing structure, or at least a subset of components of the existing structure, prior to performing finite element analysis.

Many design engineers use computer-aided design systems to design new structures. Some computer-aided design systems have some finite element analysis capabilities. In the past, engineers would use complicated hard-to-use software separate from the CAD system to perform finite element analysis. These products would use three noded plate elements or six-noded wedge elements with different local axis. It would be very difficult for a normal practicing engineer to understand the stress directions and results to qualify their designs.

One challenge with these FEA-based procedures is the complexity which requires proper connectivity between the elements. This task requires engineers to look at the boundary of the components and provide common points, which could be extremely difficult even with a simple problem of a pipe connecting to a vessel.

### SUMMARY OF VARIOUS EMBODIMENTS

Illustrative embodiments operate in a computer-aided design environment to facilitate finite element analysis of a multi-component system, which system includes a master element coupled to a dependent element.

Performing Finite Element Analysis on an object or system conventionally requires a user to have considerable experience in preparing a model of the object or system prior to performing Finite Element Analysis on the model. Such a user must be experienced in preparing models and inputs for Finite Element Analysis.

In contrast, illustrative embodiments enable a CAD operator to perform Finite Element Analysis on a multi-component system, even when that CAD operator is not experienced in preparing models and inputs for Finite Element Analysis.

Also, performing Finite Element Analysis on existing structures is more difficult than performing Finite Element Analysis on a structure that has not yet been built, but which exists in a CAD model. This is because, at least in part, a model of the existing structure must be created for use as input to Finite Element Analysis. Illustrative embodiments enable a CAD operator to perform Finite Element Analysis on a pre-existing structure by making it easier to create a model of the pre-existing structure, even when a CAD model of the pre-existing structure is not available.

Illustrative embodiments cast a shadow of an end of the dependent element, and derive mesh node points on the surface of the master component from the shadow. Illustrative embodiments then form a mesh from the mesh node points, which mesh is input to a finite element analysis engine.

A first embodiment includes a method for finite element analysis, in a computer, of a digital model of an interface between a master component and a dependent component of a physical apparatus. The method includes:
obtaining a first digital model of the master component, the master component having a master surface;
obtaining a second digital model of the dependent component, the dependent component having a longitudinal axis and a cross section defining a connecting plane;
orienting the second digital model relative to the first digital model such that the longitudinal axis of the dependent component intersects a point of intersection on the first digital model; and then
casting a shadow of the cross section of the dependent component on a surface where the dependent component intersects the surface, the shadow defining a contour at its outer edge, said contour being a curve of intersection between the master component and the dependent component.

The method also includes identifying a first group of master surface points on the surface of the master component, said first group of master surface points including a plurality of points forming the contour of the shadow on the surface of the master component;
identifying a second group of master surface points on the surface of the master component, said second group of master surface points including a plurality of points surrounding the first group of points; and
defining a mesh including a plurality of mesh elements, each mesh element defined by a set of points from the first group of master surface points and the second group of master surface points.

The method also includes submitting the mesh to a finite element analysis system and performing finite element analysis of the mesh.

In some embodiments, the surface is a surface of the master component.

In some embodiments, casting a shadow of the cross section of the dependent component on a surface includes:
creating an intermediate shadow of the cross section of the dependent component onto a two-dimensional shadow plane, said shadow plane parallel to a tangent plane tangent to the master surface at the point of intersection on the master surface where the dependent component intersects the master surface, the shadow having an outer edge and defining a contour at its outer edge, said contour being a curve of intersection between the shadow plane and the dependent component;
selecting intermediate points on the curve of intersection; and
translating said intermediate points to the master surface to produce the first group of master surface points.

In some such embodiments, the shadow plane is co-planar with the tangent plane.

In some such embodiments, the master surface includes a flat surface defining a two-dimensional plane, and wherein said flat surface includes the two-dimensional shadow plane.

In some such embodiments, the surface is the master surface and the master surface includes a curved surface at the point of intersection, and the two-dimensional shadow plane includes a floating surface disposed between the dependent component and the master component, the floating surface normal to a line that is normal to the master surface at the point of intersection.

In some embodiments, the second group of points is radially outward of the first group of points, relative to the point of intersection.

In some such embodiments, the shadow is cast by parallel light rays.

Another embodiment includes a system for finite element analysis of a digital model of an interface between a master component specified by a first digital model and a dependent component specified by a second digital model, the dependent component having a longitudinal axis and a cross section defining a connecting plane. In such embodiments, the system includes:
a CAD module configured to provide the first digital model and the second digital model;
an orientation module configured for orienting the second digital model relative to the first digital model such that the longitudinal axis of the dependent component intersects a point of intersection on the first digital model;
a shadow module configured for casting a shadow of the cross section of the dependent component on a surface where the dependent component intersects the surface, the shadow defining a contour at its outer edge, said contour being a curve of intersection between the master component and the dependent component;
a points module configured for identifying a first group of master surface points on the surface of the master component, said first group of master surface points including a plurality of points forming the contour of the shadow on the surface of the master component;
the points module also configured for identifying a second group of master surface points on the surface of the master component, said second group of master surface points including a plurality of points surrounding the first group of points;
a mesh module configured for defining a mesh including a plurality of mesh elements, each mesh element defined by a set of points from the first group of master surface points and the second group of master surface points; and
a finite element analysis module configured for submitting the mesh to a finite element analysis system and performing finite element analysis of the mesh.

In some embodiments of a system, the surface is a surface of the master component, and the shadow module is configured for casting the shadow of the cross section of the dependent component on said surface of the master component.

In some embodiments, the CAD module is further configured to provide a two-dimensional shadow plane parallel to a tangent plane tangent to the master surface at the point of intersection on the master surface where the dependent component intersects the master surface, and
the shadow module is configured for creating an intermediate shadow of the cross section of the dependent component onto a shadow plane, the intermediate shadow having an outer edge and defining a contour at its outer edge, said contour being a curve of intersection between the master component and the dependent component;
the points module is configured for selecting intermediate points on the curve of intersection; and
translating said intermediate points to the master surface to produce the first group of master surface points.

In some such embodiments, the tangent plane is co-planar with the tangent plane.

In some embodiments, the surface is a master surface of the master component, and the master surface includes a curved surface at the point of intersection, and the two-dimensional shadow plane includes a floating surface disposed between the dependent component and the master component, the floating surface normal to a line that is normal to the master surface at the point of intersection.

Another embodiment includes a non-transitory computer readable medium having computer-executable code stored thereon. The computer-executable code, when executed by a computer processor, causes the computer to execute a method, including:
providing a first digital model of the master component, the master component having a master surface;
providing a second digital model of the dependent component, the dependent component having a longitudinal axis and a cross section defining a connecting plane;
orienting the second digital model relative to the first digital model such that the longitudinal axis of the dependent component intersects a point of intersection on the first digital model;
casting a shadow of the cross section of the dependent component on a surface where the dependent component intersects the surface, the shadow defining a contour at its outer edge, said contour being a curve of intersection between the master component and the dependent component;
identifying a first group of master surface points on the surface of the master component, said first group of master surface points including a plurality of points forming the contour of the shadow on the surface of the master component;
identifying a second group of master surface points on the surface of the master component, said second group of master surface points including a plurality of points surrounding the first group of points;
defining a mesh including a plurality of mesh elements, each mesh element defined by a set of points from the first group of master surface points and the second group of master surface points; and
submitting the mesh to a finite element analysis system and performing finite element analysis of the mesh.

In some embodiments, the surface is a surface of the master component.

In some embodiments, casting the shadow of the cross section of the dependent component on a surface includes:
creating an intermediate shadow of the cross section of the dependent component onto a two-dimensional shadow plane, said shadow plane parallel to a tangent plane tangent to the master surface at the point of intersection on the master surface where the dependent component intersects the master surface, the shadow having an outer edge and defining a contour at its outer edge, said contour being a curve of intersection between the master component and the dependent component;
selecting intermediate points on the curve of intersection; and
translating said intermediate points to the master surface to produce the first group of master surface points.

In some such embodiments, the tangent plane is co-planar with the shadow plane.

In some such embodiments, the master surface includes a flat surface defining a two-dimensional plane, and wherein said flat surface includes the two-dimensional shadow plane.

In some embodiments, the surface is the master surface and the master surface includes a curved surface at the point of intersection, and the two-dimensional shadow plane includes a floating surface disposed between the dependent component and the master component, the floating surface normal to a line that is normal to the master surface at the point of intersection.

In some embodiments, the shadow is cast by parallel light rays.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically illustrates an embodiment of a system for finite element analysis of a digital model of an interface between a master component and a dependent component of a physical apparatus;

FIG. 1B schematically illustrates a block diagram of an embodiment of a system for finite element analysis of a digital model of an interface between a master component and a dependent component of a physical apparatus;

FIG. 2A is a flowchart of an embodiment of a method for performing a finite element analysis of a digital model of an interface between a master component and a dependent component of a physical apparatus;

FIG. 2B schematically illustrates a user interface;

FIG. 3 is a flowchart of an embodiment of a method for casting a simulated shadow in a computer system;

FIG. 4 is a flowchart of an embodiment of a method for modeling an existing structure;

FIG. 5A schematically illustrates an embodiment of a cylindrical multi-component system;

FIG. 5B schematically illustrates an embodiment of components of a cylindrical multi-component system;

FIG. 5C schematically illustrates an embodiment of a dependent component of a cylindrical multi-component system;

FIG. 5D schematically illustrates an embodiment of a rectangular multi-component system;

FIG. 5E schematically illustrates an embodiment of components of a rectangular multi-component system;

FIG. 6A schematically illustrates an embodiment of an embodiment of casting a direct shadow on a master component;

FIG. 6B: A schematically illustrates an embodiment a shadow as cast on a master component;

FIG. 7A schematically illustrates an embodiment of casting an intermediate shadow on a shadow plane;

FIG. 7B schematically illustrates an embodiment of casting an intermediate shadow on a shadow plane;

FIG. 7C schematically illustrates an embodiment of casting an intermediate shadow on a shadow plane;

FIG. 8A schematically illustrates an embodiment of points derived from a shadow;

FIG. 8B schematically illustrates an embodiment of points derived from a shadow;

FIG. 8C schematically illustrates an embodiment of concentric rings of points derived from a shadow;

FIG. 8D schematically illustrates an embodiment of a mesh defined from concentric rings of points derived from a shadow;

FIG. 8E schematically illustrates an embodiment of a mesh defined from a plurality of points.

### DESCRIPTION OF ILLUSTRATIVE EMBODIMENTS

Illustrative embodiments present an improvement over methods and systems for performing finite element analysis of a multi-component (i.e., a system that includes a plurality of physically connected components), even if that engineer does not have the expertise typically held by an engineer of ordinary skill in the field of finite element analysis. A typical computer-aided design system operator does not have the skills or experience to perform finite element analysis on a finite element analysis system.

Some embodiments enable an engineer using a computer-aided design system to perform finite element analysis on a multi-component system being designed by the engineer.

Some embodiments enable an engineer using a computer-aided design system to perform finite element analysis on a pre-existing (i.e., already-built) multi-component system. For example, in some embodiments, measurements of a pre-existing multi-component system may be translated into models on the computer-aided design system, and finite element analysis performed on the models. Some embodiments may scan a pre-existing multi-component system using a scanning modality, such as a scanning apparatus that produces a point cloud of the system. For example, some embodiments scan the pre-existing multi-component system using a scanner mounted to a drone.

Some embodiments allow an engineer to connect two or more components easily without having to deal with complex functions to represent the intersection of the curve or making any assumptions. This feature can be implemented in a software easily to create four-noded meshes to simplify the interpretation of the results.

Some embodiments implemented as a computer program product having a computer usable medium with computer readable program code thereon. The computer readable code may be read and utilized by a computer system in accordance with conventional processes.

Illustrative embodiments operate in a computer-aided design environment to facilitate finite element analysis of a multi-component system, which system includes a master element coupled to a dependent element. Illustrative embodiments cast a shadow of an end of the dependent element, and derive mesh node points on the surface of the master component from the shadow. Illustrative embodiments then form a mesh from the mesh node points, which mesh is input to a finite element analysis engine.

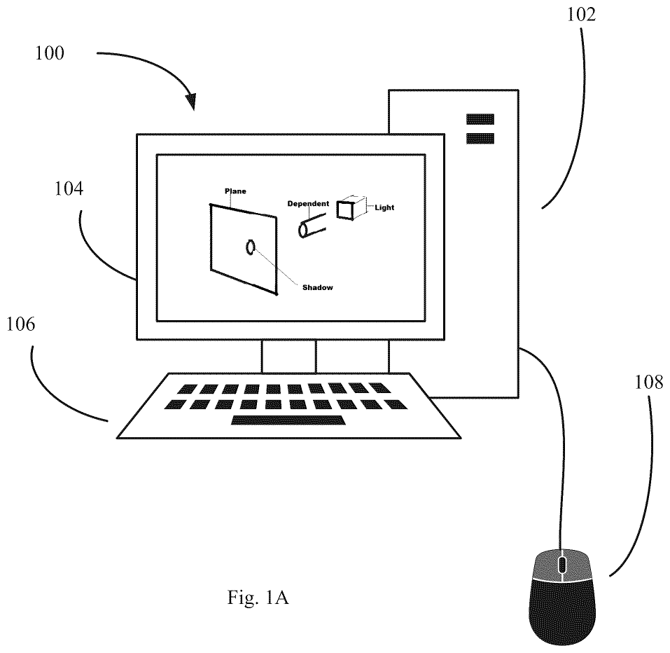

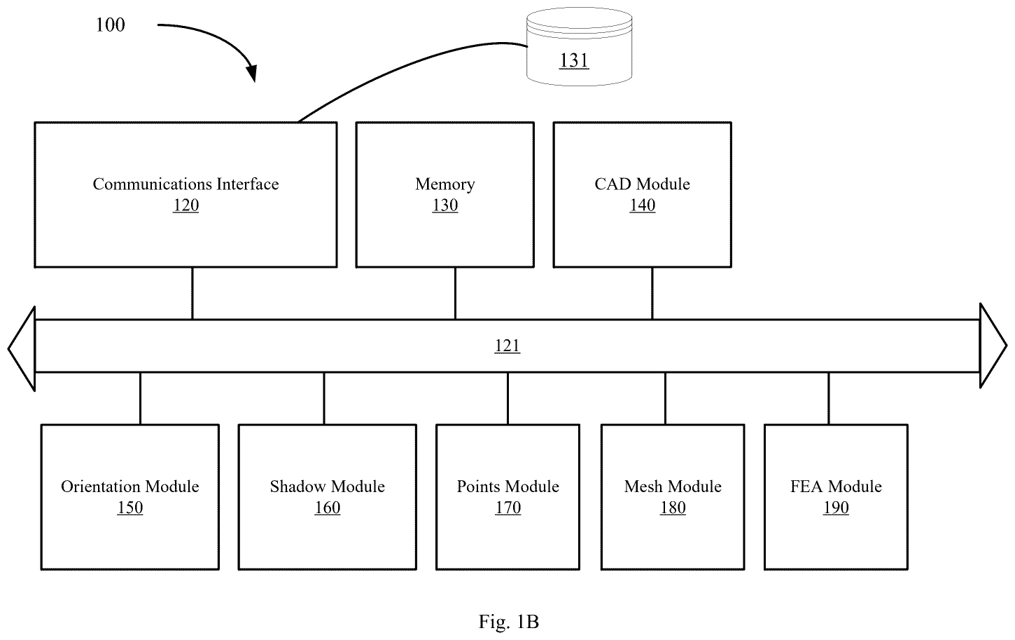

FIG. 1A schematically illustrates an embodiment of a CAD system 100 for finite element analysis of a digital model of an interface between a master component and a dependent component of a physical apparatus. The system includes a central processing unit 102 in data communication with a computer monitor having a display screen 104, a keyboard 106, and a computer mouse 108. A system operator may use the keyboard 106 and/or mouse 108 to provide use input to the system, and the central processing unit 103 may display images (e.g., CAD images and finite element analysis images) on the screen 104.

FIG. 1B schematically illustrates a block diagram of an embodiment of a system 100 for finite element analysis of a digital model of an interface between a master component and a dependent component of a physical apparatus. The system 100 includes a set of modules interconnected in data communication via a communications bus 121. The modules include a communications interface 120 configured to communicate with other computers or systems (e.g., a network; a cloud of components; a remote database 131). The system also includes a memory 130 which may store, among other things, CAD designs and executable software. The system also includes a CAD module 140 configured to render an image of the CAD drawing for display on a screen 104; an orientation module 150 configured to orient a dependent component relative to a master component as described herein, a shadow module 160 configured to display a CAD cast a shadow of a component in a CAD drawing; a points module 170 configured to select points from a shadow; a mesh module 180 configured to generate a finite element analysis mech from selected points; and a finite element analysis module 190 configured to perform finite element analysis using the mesh.

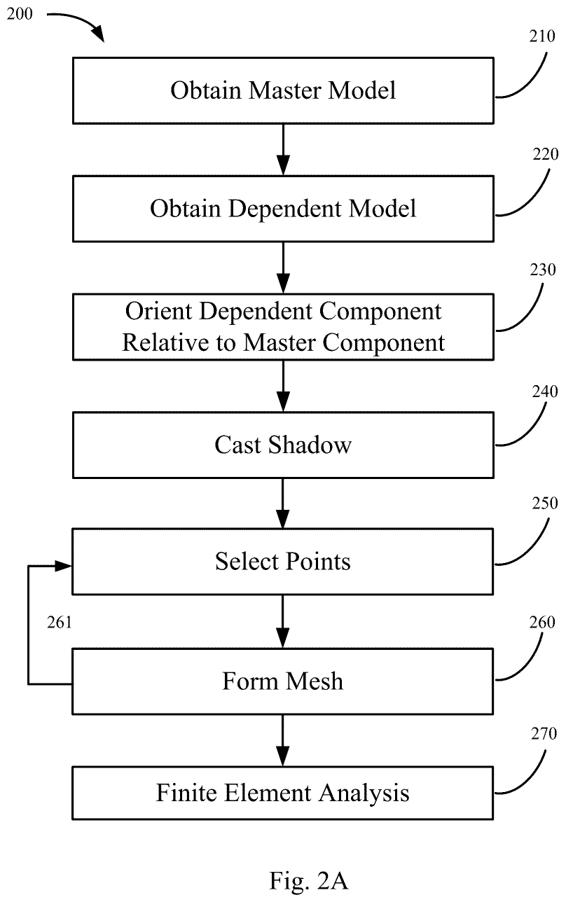

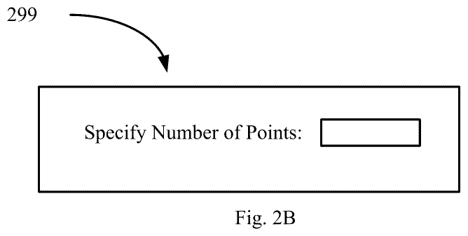

FIG. 2A is a flowchart of an embodiment of a method 200 for performing a finite element analysis of a digital model of an interface between a master component and a dependent component of a physical apparatus. The embodiment of FIG. 2A may be considered to cast a shadow 610 directly onto the surface 512 of the master component 510.

Step 210 includes obtaining a CAD model of the master component.

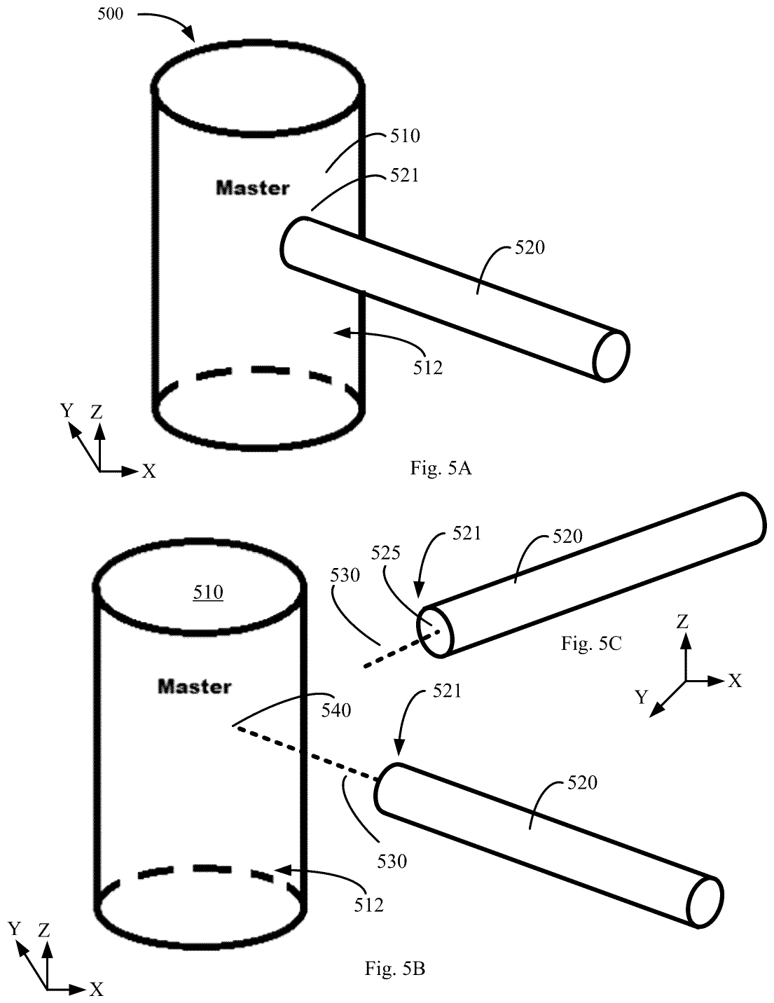

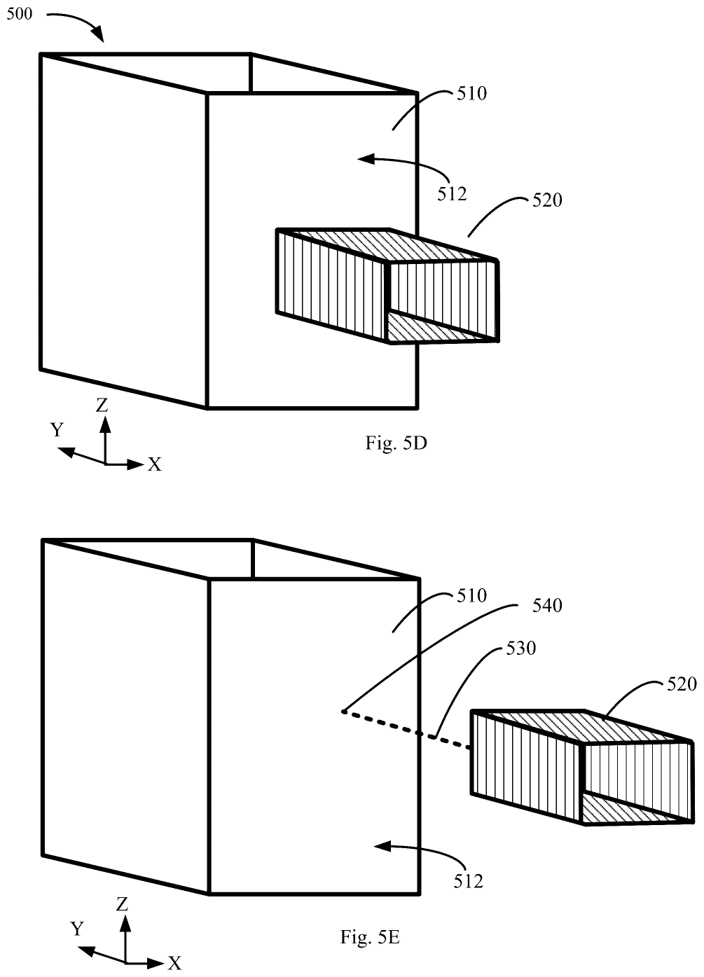

An illustrative example of a master component 510 and a dependent component 520 are schematically illustrated in FIG. 5A, FIG. 5B and FIG. 5C. An illustrative example of another master component 510 and another dependent component 520 are schematically illustrated in FIG. 5D, FIG. 5E.

In illustrative embodiments, the master component 510 has a master surface 512 and an interface point 540 at which interface point 540 the dependent component 520 meets the master component 510. In such embodiments, the dependent component 520 has an interface area (or interface end) 521 at which the dependent component 520 meets the surface 512 of the master component 510. In illustrative embodiments, the interface area 521 defines an interface plane 525. The interface plane 525 defines a longitudinal axis 530 normal to the interface plane 525. In some embodiments, the system 100 displays the longitudinal axis on the computer screen 104.

Step 230 includes orienting, in a CAD environment, the model of the dependent component 520 relative to the model of the master component 510. Such orienting may be referred-to as orienting the dependent component 520 relative to the master component 510. In illustrative embodiments, orienting the dependent component 520 relative to the master component 510 includes displaying a point of intersection 540 where the longitudinal axis 530 of dependent component 520 meets the surface 512 of the master component 510.

Step 240 includes casting, in the CAD environment, a shadow 610 of the interface plane 525 onto the surface 512 of the master component 510. The shadow 610 has a contour at its outer edge 611, which contour depends in part on the shape of the interface plane 525 and the shape (or contour) of the surface 512 of the master component 510.

Typical CAD systems have the ability to cast a shadow of an element of a CAD drawing, such as from a virtual light source 550. In preferred embodiments, the shadow 610 is cast using light rays (e.g., from the virtual light source 500) that are parallel to one another. In some embodiments, the shadow 610 is cast using light rays (e.g., from the virtual light source 500) that are not parallel to on another, but preferably have a small angle relative to one another. In some such embodiments, the angle between such non-parallel light rays may be 1 degree, between one degree and two degrees, 2 degrees, between 2 degrees and 3 degrees, 3 degrees, between 4 degrees and 5 degrees, or 5 degrees. In some embodiments, such angle between virtual light rays may depend, for example, on the way in which the virtual light source 550 generates the light rays. In some embodiments, such angle between virtual light rays may depend, for example, on how far the virtual light source is, in the CAD drawing, from the interface plane 525 of the dependent component 520. In general, a greater distance between the virtual light source 500 and the interface plane 525 is preferred over a smaller distance because virtual light ray impinging on the interface plane 525 of the dependent component tend to be more nearly parallel to one another (i.e., have a smaller angle relative to one another) with greater distance.

Step 250 includes selecting points 899 from the shadow 610, which points will form the basis of a mesh for finite element analysis.

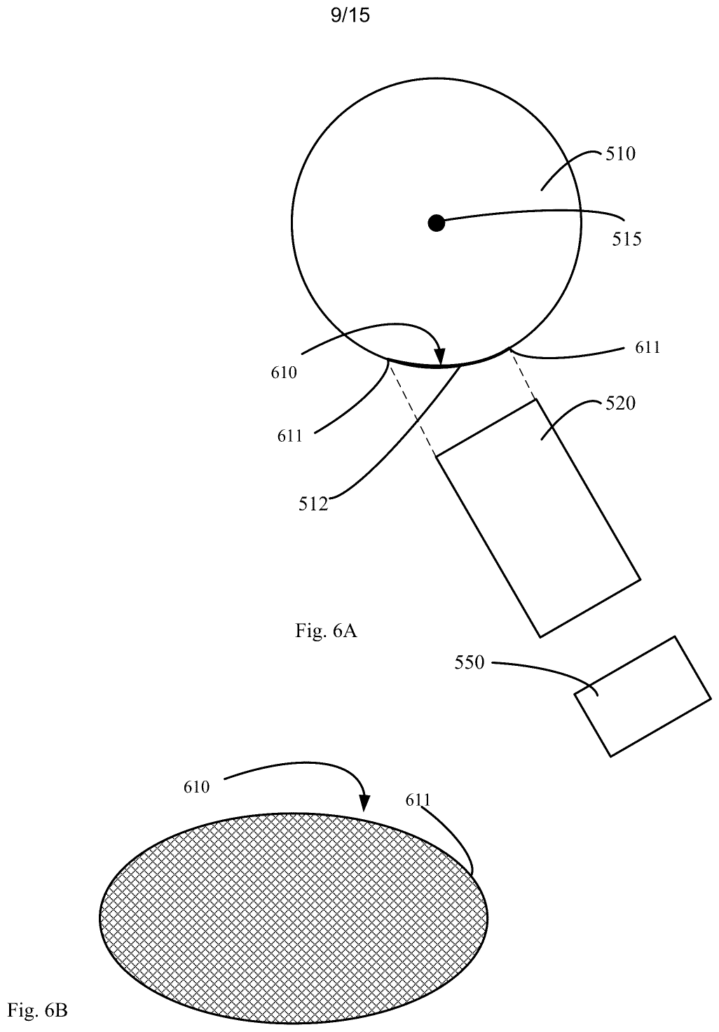

In illustrative embodiments, step 250 includes identifying a first group of points on the edge 611 of the shadow 610, as schematically illustrated in FIG. 6A and FIG. 6B, for example. That first group of points includes a plurality of points forming the contour of the shadow 610.

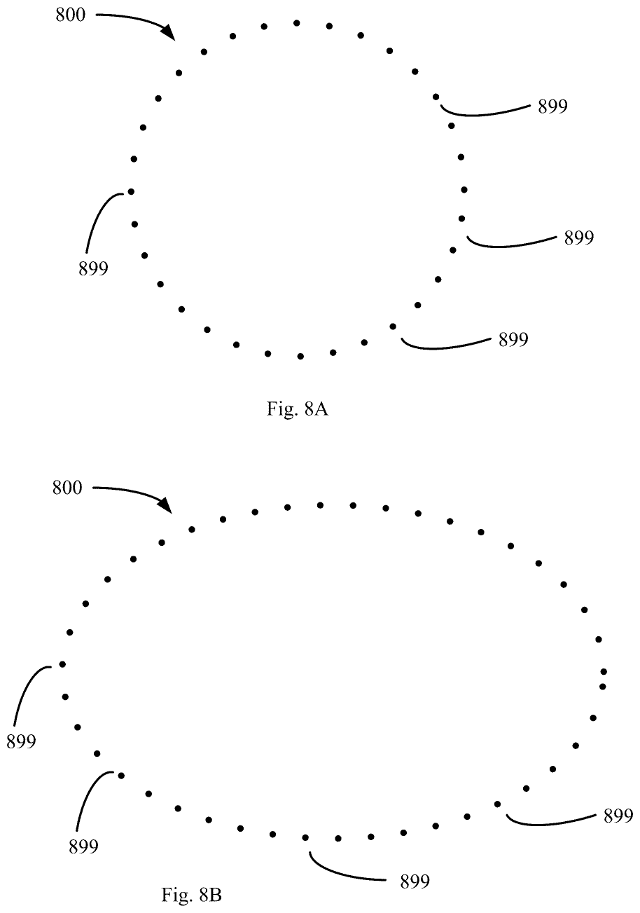

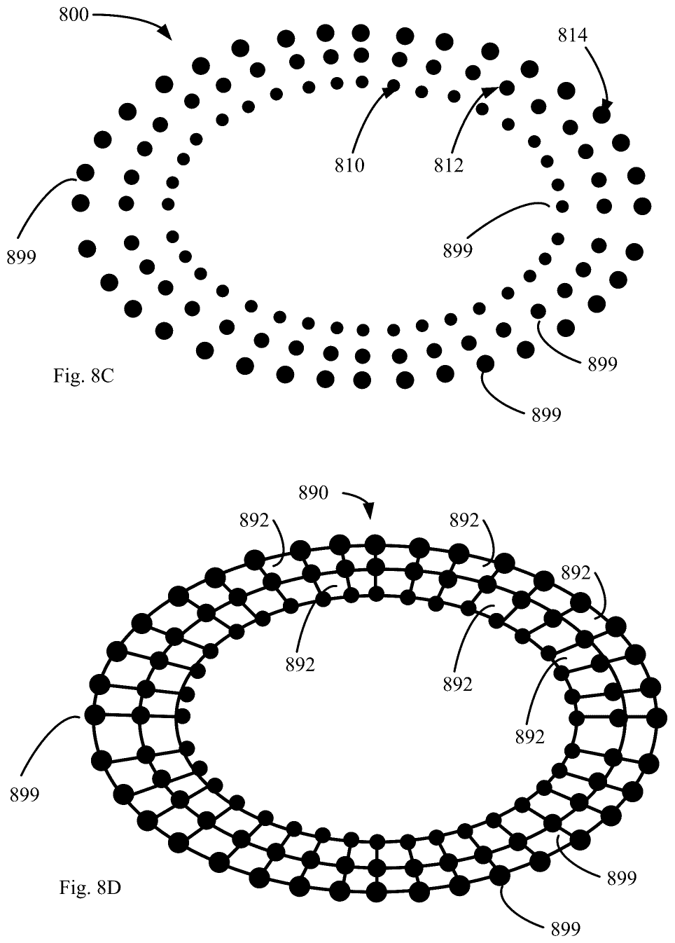

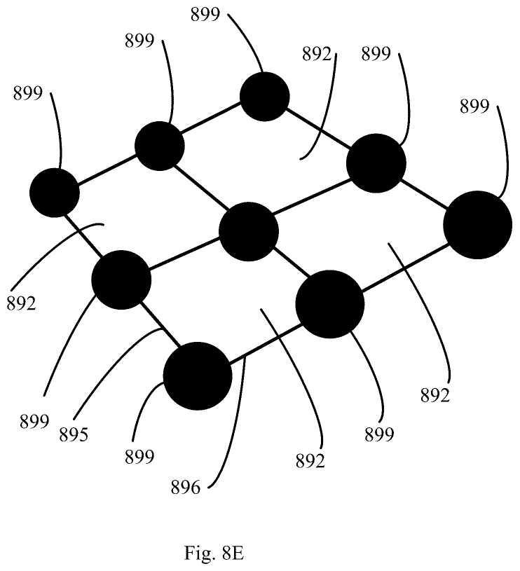

An embodiment of a first group 800 of points 899 is schematically illustrated in FIG. 8A. The contour of the first group of points 800 in FIG. 8A forms a circle, such as would have been derived from a circular shadow, such as a shadow cased on a planar surface by a dependent component 520 having a circular cross-section.

Another embodiment of a first group of points 800 is schematically illustrated in FIG. 8B. The contour of the first group of points 800 in FIG. 8B forms an ellipse, such as would have been derived from an elliptical shadow, such as a shadow cased on a planar surface by a dependent component 520 having a circular cross-section an having a longitudinal axis 530 that intersects a planar surface 512 of a primary component 510, or a shadow plane 620, at an angle that is not a right angle.

Step 250 also includes identifying at least one a second group of points of the shadow, each such second group points including a plurality of points 899 surrounding the first group 800 of points. In illustrative embodiments, step 250 includes identifying a plurality of second groups of points, each such group forming a path around the first group of points. In illustrative embodiments, each second group of points is concentric with the first group of points. In some embodiments in which the shadow 610 is cast directly on the surface 512 of the first component 510, the first group of points and the second group of points may be considered to be coincident with corresponding points on the surface 512 of the first component 510.

An illustrative embodiment of a second group of points 810 is schematically illustrated in FIG. 8C. In this embodiment, the second group of points 810 forms an ellipse, and is concentric with (i.e., has the same center point as) the first group of points 810.

FIG. 8C also schematically illustrates an addition second group of points 812, and a third second group of points, 814.

In some embodiments a system operator may identify the points based on user experience, for example via a user interface 299 generated by and presented on a computer monitor of a CAD system 100, as schematically illustrated in FIG. 2B. In some embodiments, a system operator may identify a portion of the CAD drawing, and may specify how may points should be identified in within that portion and the CAD system 100 (e.g., a points module 170) automatically identifies the points based on that operator input. In some embodiments, a system operator may specify a distance between adjacent points, and the CAD system 100 (e.g., a points module 170) automatically identifies the points based on that operator input. In some embodiments, methods and systems start with a default number of points on each group of points and then automatically assess the respective aspect ratios of the resulting mesh elements 892 (as described below) to determine whether to repeat step 250 to identify additional points. In illustrative embodiments, the default number of points may be 12 points, for example. In some embodiments, the default number of points may be 20 points, a number of points not less than 20 points but less than 30 points; 30 points, a number of points not less than 30 points but less than 40 points, 40 points, a number of points not less than 40 points but less than 50 points, 50 points, a number of points not less than 50 points but less than 50 points, 100 points, a number of points not less than 100 points but less than 200 points, to name but a few examples.

As described below, the points are used to form a plurality of mesh elements 892, as schematically illustrated in FIG. 8D and FIG. 8E. In some embodiments, the number of points is selected, specified or determined so that each mesh element 892 has an aspect ratio of equal to or less than 4:1, where the aspect ratio of a mesh element is defined as the ratio of the length of the mesh element to the width of the mesh element. For example, in FIG. 8E, one mesh element 892 has a first side 895 representing the length of the mesh element 892, and a second side 896 representing the width of the mesh element 892, where the first side 895 is immediately adjacent to the second side, and the first side 895 has a length that is equal to or greater than the length of the second side 896. For example, if the first side 895 has a length of 1.7 millimeters, and the second side 896 has a length of 0.8 millimeters, the aspect ratio of the mesh element would be 1.7 divided by 0.8, which equals a ratio of 2.125, which is less than 4:1. As another example, if the first side 895 has a length of 4.0 millimeters, and the second side 896 has a length of 1.7 millimeters, the aspect ratio of the mesh element would be 4.0 divided by 1.7, which equals a ratio of 2.35, which is less than 4:1. In illustrative embodiments, if the aspect ratio of any mesh element of the plurality of mesh elements is greater than 4:1, then the number of points is insufficient, and the operator, or the system, may increase the number of points until the aspect ratio of each mesh element 892 is equal to or less than 4.0. In general, the more mesh elements used for finite element analysis, the more accurate the results of the finite element analysis. Although examples herein are described with reference to an aspect ratio of less than or equal to 4:1, other embodiments may use a different aspect ratio. For example, depending on the structure being subject to finite element analysis and the experience level of the system operator, some embodiments may specify or require an a different pre-specified aspect ratio, such as an aspect ratio of less than or equal to 1:1; less than or equal to 2:1; less than or equal to 3:1; less than or equal to 5:1; less than or equal to 6:1; less than or equal to 7:1; or less than or equal to 8:1.

Step 260 includes forming a mesh 890 from the identified points (i.e., points identified at step 250), which mesh includes a plurality of mesh elements 892. This may be done automatically by the CAD system 100, such as by a mesh module 180. In illustrative embodiments, each mesh element is defined by four of the identified points, and may be referred-to as a four-noded mesh element or a “quadrilateral” mesh element. A mesh of four-noded mesh elements may be referred-to as a four-noded mesh. A four-noded mesh 890 is schematically illustrated in FIG. 8D, for example.

In preferred embodiments, each mesh element shares at least one node (i.e., one if the identified points) in common with an adjacent mesh element, and no node is part of only a single mesh element. Note that a mesh generated for generating an image, such as in computer animation, video games, and even a conventional CAD drawing, etc., is not sufficient to serve as a mesh generated by step 260, and is not sufficient for use as input for finite element analysis, because in those applications, a gap between mesh elements is acceptable in that any lack of fidelity in the rendered image will not degrade the image (relative to an image rendered from a mesh in which there are not gaps between adjacent mesh elements) to the point that a human eye would notice the degradation.

In illustrative embodiments, each mesh element 892 has an aspect ratio of less than or equal to 4:1, as described above. Some embodiments determine which mesh element 892 of the plurality of mesh elements has the largest aspect ratio, and if the aspect ratio of that mesh element is greater than 4:1, then the method loops back (step 261) to step 250 and increases the number of identified points and repeats step 260 until each mesh element 892 has an aspect ratio of less than or equal to 4:1 (i.e., an aspect ratio not greater than 4:1).

Step 270 includes performing finite element analysis of the multi-component object 500 based on the mesh 890 generated at step 260. The mesh 890 is input to, and used by, a finite element analysis engine (e.g., finite element analysis module 190).

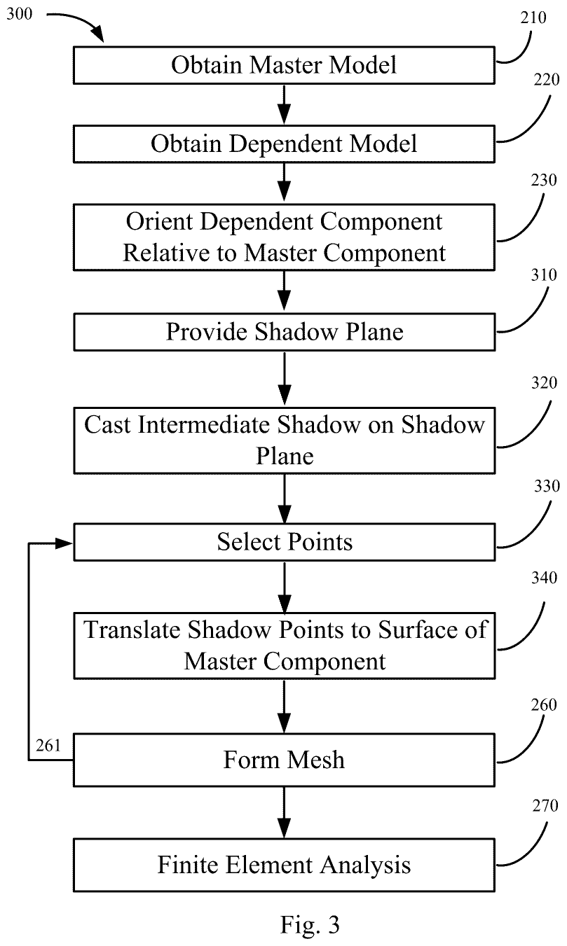

FIG. 3 is a flowchart of an embodiment of a method 300 for performing a finite element analysis of a digital model of an interface between a master component and a dependent component of a physical apparatus. The embodiment of FIG. 3 may be considered to cast a shadow 610 indirectly onto the surface 512 of the master component 510 because the method 300 includes casting an intermediate shadow 630 on a shadow plane 260 (rather than casting the shadow directly on the surface 512 master component 510), and then translating points from the intermediate shadow 630 onto the surface 512 master component 510.

In the method 300, step 210, step 220, step 230, step 260 and step 270 are the same as described above for method 200.

Rather than cast a shadow 610 directly onto the surface 512 master component 510, however, method 300 (after step 210, step 220 and step 230) provides a shadow plane 620 at step 310.

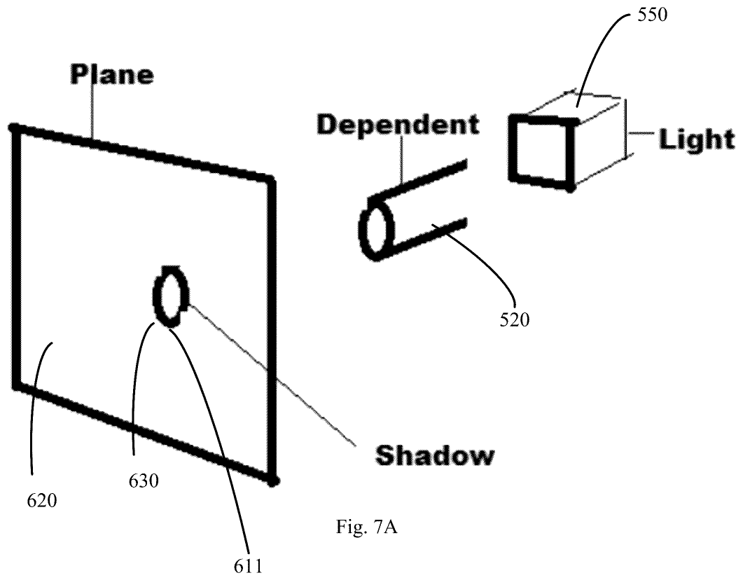

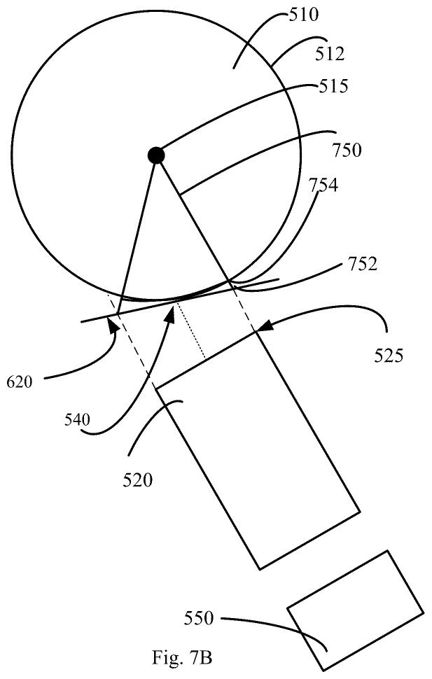

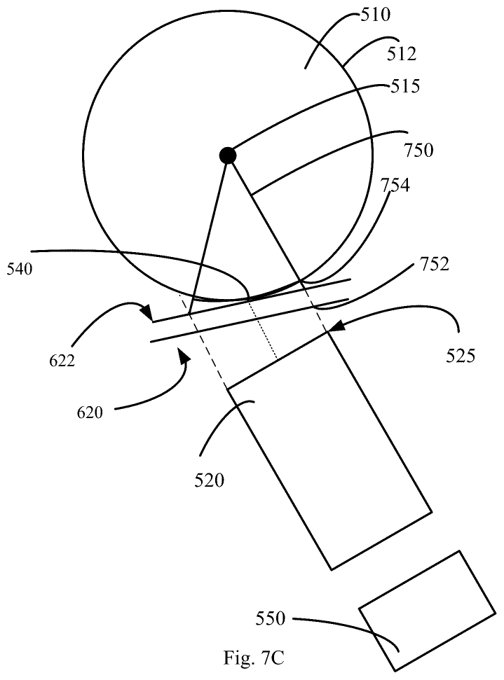

In illustrative embodiments, the shadow plane is parallel to a tangent plane 622, which tangent plane 622 is tangent to the master surface 512 at the point of intersection 540 where the dependent component 520 intersects the master surface 512. In some embodiments, the shadow plane 620 is co-planar with the tangent plane 622, as schematically illustrated in FIG. 7B.

In some embodiments, the shadow plane 620 is not co-planar with the tangent plane 622, and is disposed between the tangent plane 622 (e.g., between the point of intersection 540) and the dependent component 520, as schematically illustrated in FIG. 7C (such a shadow plane may be referred-to as a “floating” plane). In some embodiments, the master surface 512 comprises a flat surface defining a two-dimensional plane, and that flat surface is the two-dimensional shadow plane.

The method 300 then casts an intermediate shadow 630 on the shadow plane 620 at step 320. An embodiment of a shadow plane 620 and an embodiment of an intermediate shadow 630 are schematically illustrated in FIG. 7A. In preferred embodiments, the intermediate shadow 630 is cast using light rays (e.g., from the virtual light source 500) that are parallel to one another. In some embodiments, the intermediate shadow 630 is cast using light rays (e.g., from the virtual light source 500) that are not parallel to on another, but preferably have a small angle relative to one another. In some such embodiments, the angle between such non-parallel light rays may be 1 degree, between one degree and two degrees, 2 degrees, between 2 degrees and 3 degrees, 3 degrees, between 4 degrees and 5 degrees, or 5 degrees. In some embodiments, such angle between virtual light rays may depend, for example, on the way in which the virtual light source 550 generates the light rays. In some embodiments, such angle between virtual light rays may depend, for example, on how far the virtual light source is, in the CAD drawing, from the interface plane 525 of the dependent component 520. In general, a greater distance between the virtual light source and the interface plane 525 is preferred to a smaller distance because virtual light ray impinging on the interface plane 525 of the dependent component tend to be more nearly parallel to one another (i.e., have a smaller angle relative to one another) with greater distance.

At step 330, subsequent to step 320, the method 300 selects points on the shadow plane 620 from the intermediate shadow 630. In illustrative embodiments, step 330 includes identifying a first group of points on the edge 611 of the intermediate shadow 630. That first group of points includes a plurality of points forming the contour of the intermediate shadow 630. In illustrative embodiment, the points of said first group of points are selected to be spaced apart from one another, so that the first group of points does not form a continuous curve. In some illustrative embodiments, the spacing between the points of the first group of points is specified by a CAD operator. In some illustrative embodiments, the spacing between the points of the first group of points is determined as a fraction of the circumference of the dependent component 520, where the “circumference” is the total distance around the outside surface of the dependent component 520. For example, in some embodiments, the spacing between the points of the first group of points is set at one percent (1%) of the circumference of the dependent component 520. In some embodiments, the spacing between the points of the first group of points is set at one-half percent (0.5%) of the circumference, or one quarter (0.25%), or two percent (2%), of the circumference of the dependent component 520.

Step 330 also includes identifying at least one second group of points of the intermediate shadow 630 (and in some embodiments, includes identifying a plurality of such second groups of points), each such second group points including a plurality of points surrounding the first group of points. In illustrative embodiments, step 330 includes identifying a plurality of second groups of points, each such group forming a path around the first group of points. In illustrative embodiments, each second group of points is concentric with the first group of points.

In some embodiments, one or more of such second group of points is selected so that the points are disposed within (i.e., are surrounded by) the first group of points.

Each point identified in step 330 may be referred-to as a shadow point.

Subsequent to step 330, step 340 translates the shadow points identified at step 330 from the shadow plain 620 to the surface 512 of the master component 510.

In the case in which the master surface 512 is planar, the act of translating shadow points from the shadow plain 620 to the surface 512 of the master component 510 includes simply projecting each point from the shadow plane 620 to the master surface 512 along a line normal to the shadow plane 620.

In the case where the master component 510 has a surface 512 that is curved (for example, with a constant radius such as when the master component 510 has a circular cross-section), step 340 translates the points identified at step 330 from the intermediate shadow 630 to the surface 512 of the master component 510 by identifying a reference point 515 internal to the master component 510. In illustrative embodiments, the reference point 515 is at the geometric center of the cross-section of the master component 510. For example, in FIG. 7B, the master component 510 has a circular cross-section, and a reference point 515 at the center of the circular cross section.

Then, for each shadow point identified at step 330, step 340 identifies a corresponding mesh node point on the surface 512 of the master component 510 as a point on the surface 512 of the master component 510 at which a line segment between a shadow point identified at step 330 and said reference point crosses the surface 512 of the master component.

For example, in FIG. 7B, the method 300, and system 100, defines a line segment 750 extending from the reference point 515 to a shadow point 752 on the shadow plane. The corresponding mesh node point 754 lies at the intersection. Step 340 thereby identifies one mesh node point on the surface 512 of the primary component 510 for (and corresponding to) each shadow point on the shadow plane 620.

The mesh nodes on the surface 512 of the primary component 510 form a contour that is similar to, but in illustrative embodiments is not identical to, the intermediate shadow 630. For example, in circumstances in which the surface 512 of the primary component 510 is curved, the curve of the surface will result in the contour of the mesh node points being a distorted (differently-shaped) version of the intermediate shadow 630.

Moreover, at step 340, each mesh node point is, relative to its corresponding intermediate shadow point, biased towards the longitudinal axis 530. As a consequence, the contour of the mesh node points on the surface 512 of the primary component 510 is smaller than the intermediate shadow 630. The contour of the mesh node points on the surface 512 of the primary component 510 may be beneficial in that it identified mesh node points that are closer to the longitudinal axis 530, and therefore closer to the center of the dependent component 520. This could be beneficial, for example, when the dependent component 520 is a duct, pipe or cylinder having walls with unknown thickness, or when the dependent component 520 is a solid cylinder. In such cases, at least some of the mesh node points represent points within the duct walls, pipe walls, and/or in the interior of the cylinder, which points might otherwise have been omitted from a mesh and finite element analysis, as described herein.

Subsequent to step 340, the method 300 forms a mesh at step 260, and performs finite element analysis, using the mesh as input, at step 270, as described above in connection with method 200.

In illustrative embodiments, each mesh element 892 has an aspect ratio of less than or equal to 4:1, as described above. Some embodiments determine which mesh element 892 of the plurality of mesh elements has the largest aspect ratio, and if the aspect ratio of that mesh element is greater than 4:1, then the method loops back (step 261) to step 330 and increases the number of shadow points and repeat steps 330 and step 260 until each mesh element 892 has an aspect ratio of less than or equal to 4:1 (i.e., an aspect ratio not greater than 4:1).

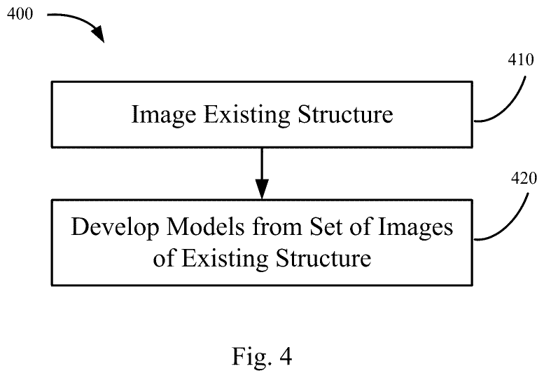

FIG. 4 is a flowchart of an embodiment of a method for modeling an existing (i.e., already-constructed) multi-component structure.

Step 410 includes scanning the existing multi-component system with a scanning modality to create an image set of one or more images of the system, such as a scanning apparatus that produces a set of one or more photographs of the system, or a point cloud of the system. In illustrative embodiments, the set of images includes an image of at least a portion of the primary component, at least a portion of the dependent component, and an image of the intersection of the dependent component with the primary component. In some embodiments, the scanning modality includes flyable drone, which drone can create the set of images under control of a drone operator.

Step 420 includes generating a CAD model of the master component 510 and a CAD model of the dependent component 520 from the set of images of the system produced by the scanning modality. In some embodiments, such models are created by a CAD operator, based on the CAD operator's observation of the image set. In some embodiments, such models are created by an artificial intelligence agent, which artificial intelligence agent may be implemented by an artificial intelligence module 141 of system 100. Such an artificial intelligence agent is trained to recognize system components based on a training set of images. Such components may be, for example, pipes, tubes, tanks, struts, and beams, to name but a few examples, and the training set includes images of such components. The CAD model generated in this way is then employed as input to the methods and systems described herein.

A list of certain reference numbers here is presented below:
100: CAD system;
102: CAD system processing unit;
104: Computer monitor;
106: Keyboard;
108: Computer mouse;
120: Communications interface;
121: Bus;
130: Memory;
140: Shadow module;
150: Orientation module;
160: Shadow module;
170: Points module;
180: Mesh module;
190: Finite element analysis module;
510: Master component;
515: Center point of cross-section of master component;
520: Dependent component;
521: Interface end of dependent component;
525: Interface plane of dependent component;
530: Longitudinal axis;
540: Point of intersection;
550: Light;
610: Shadow on surface of master component;
611: Outer edge of shadow;
620: Shadow plane;
630: Intermediate shadow on shadow plane;
890: Mesh;
892: Mesh element;
895: Edge of mesh element;
896: Edge of mesh element;
899: Point.

Various embodiments may be characterized by the potential claims listed in the paragraphs following this paragraph (and before the actual claims provided at the end of this application). These potential claims form a part of the written description of this application. Accordingly, subject matter of the following potential claims may be presented as actual claims in later proceedings involving this application or any application claiming priority based on this application. Inclusion of such potential claims should not be construed to mean that the actual claims do not cover the subject matter of the potential claims. Thus, a decision to not present these potential claims in later proceedings should not be construed as a donation of the subject matter to the public.

Without limitation, potential subject matter that may be claimed (prefaced with the letter “P” so as to avoid confusion with the actual claims presented below) includes:

P1. A method for finite element analysis, in a computer, of a digital model of an interface between a master component and a dependent component of a physical apparatus, the method comprising:
obtaining a first digital model of the master component, the master component having a master surface;
obtaining a second digital model of the dependent component, the dependent component having a longitudinal axis and a cross section defining a connecting plane;
orienting the second digital model relative to the first digital model such that the longitudinal axis of the dependent component intersects a point of intersection on the first digital model;
casting a shadow of the cross section of the dependent component on a surface where the dependent component intersects the surface, the shadow defining a contour at its outer edge, said contour being a curve of intersection between the master component and the dependent component;
identifying a first group of master surface points on the surface of the master component, said first group of master surface points comprising a plurality of points forming the contour of the shadow on the surface of the master component;
identifying a second group of master surface points on the surface of the master component, said second group of master surface points comprising a plurality of points surrounding the first group of points;
defining a mesh comprising a plurality of mesh elements, each mesh element defined by a set of points from the first group of master surface points and the second group of master surface points; and
submitting the mesh to a finite element analysis system and performing finite element analysis of the mesh.

P2. The method of P1, wherein the surface is a surface of the master component.

P3. The method of any of P1-P2, wherein casting a shadow of the cross section of the dependent component on a surface comprises:
creating an intermediate shadow of the cross section of the dependent component onto a two-dimensional shadow plane, said shadow plane parallel to a tangent plane tangent to the master surface at the point of intersection on the master surface where the dependent component intersects the master surface, the shadow having an outer edge and defining a contour at its outer edge, said contour being a curve of intersection between the shadow plane and the dependent component;
selecting intermediate points on the curve of intersection; and
translating said intermediate points to the master surface to produce the first group of master surface points.

P4. The method of P3, wherein the shadow plane is co-planar with the tangent plane.

P5. The method of P3, wherein the master surface comprises a flat surface defining a two-dimensional plane, and wherein said flat surface comprises the two-dimensional shadow plane.

P6. The method of P3, wherein the surface is the master surface and the master surface comprises a curved surface at the point of intersection, and the two-dimensional shadow plane comprises a floating surface disposed between the dependent component and the master component, the floating surface normal to a line that is normal to the master surface at the point of intersection.

P7. The method of any of P1-P6, wherein the second group of points is radially outward of the first group of points, relative to the point of intersection, and each mesh element of the plurality of mesh elements has an aspect ratio of less than or equal to 4:1.

P8. The method of any of P1-P7, wherein the shadow is cast by parallel light rays.

P9. A system for finite element analysis of a digital model of an interface between a master component specified by a first digital model and a dependent component specified by a second digital model, the dependent component having a longitudinal axis and a cross section defining a connecting plane, the system comprising:
a CAD module configured to provide the first digital model and the second digital model;
an orientation module configured for orienting the second digital model relative to the first digital model such that the longitudinal axis of the dependent component intersects a point of intersection on the first digital model;
a shadow module configured for casting a shadow of the cross section of the dependent component on a surface where the dependent component intersects the surface, the shadow defining a contour at its outer edge, said contour being a curve of intersection between the master component and the dependent component;
a points module configured for identifying a first group of master surface points on the surface of the master component, said first group of master surface points comprising a plurality of points forming the contour of the shadow on the surface of the master component;
the points module also configured for identifying a second group of master surface points on the surface of the master component, said second group of master surface points comprising a plurality of points surrounding the first group of points;
a mesh module configured for defining a mesh comprising a plurality of mesh elements, each mesh element defined by a set of points from the first group of master surface points and the second group of master surface points; and
a finite element analysis module configured for submitting the mesh to a finite element analysis system and performing finite element analysis of the mesh.

P10. The system of P9, wherein the surface is a surface of the master component, and the shadow module configured for casting the shadow of the cross section of the dependent component on a surface of the master component.

P11. The system of any of P9-P10, wherein the system further comprises:
the CAD module is further configured to provide a two-dimensional shadow plane parallel to a tangent plane tangent to the master surface at the point of intersection on the master surface where the dependent component intersects the master surface, and
the shadow module is configured for creating an intermediate shadow of the cross section of the dependent component onto a shadow plane, the intermediate shadow having an outer edge and defining a contour at its outer edge, said contour being a curve of intersection between the master component and the dependent component;
the points module is configured for selecting intermediate points on the curve of intersection; and
translating said intermediate points to the master surface to produce the first group of master surface points.

P12. The system of P11, wherein the tangent plane is co-planar with the tangent plane.

P13. The system of P11, wherein the surface is a master surface of the master component, and the master surface comprises a curved surface at the point of intersection, and the two-dimensional shadow plane comprises a floating surface disposed between the dependent component and the master component, the floating surface normal to a line that is normal to the master surface at the point of intersection.

P14. A non-transitory computer readable medium having computer-executable code stored thereon, the computer-executable code, when executed by a computer processor, executing a method, the method comprising:
providing a first digital model of the master component, the master component having a master surface;
providing a second digital model of the dependent component, the dependent component having a longitudinal axis and a cross section defining a connecting plane;
orienting the second digital model relative to the first digital model such that the longitudinal axis of the dependent component intersects a point of intersection on the first digital model;
casting a shadow of the cross section of the dependent component on a surface where the dependent component intersects the surface, the shadow defining a contour at its outer edge, said contour being a curve of intersection between the master component and the dependent component;
identifying a first group of master surface points on the surface of the master component, said first group of master surface points comprising a plurality of points forming the contour of the shadow on the surface of the master component;
identifying a second group of master surface points on the surface of the master component, said second group of master surface points comprising a plurality of points surrounding the first group of points;
defining a mesh comprising a plurality of mesh elements, each mesh element defined by a set of points from the first group of master surface points and the second group of master surface points; and
submitting the mesh to a finite element analysis system and performing finite element analysis of the mesh.

P15. The non-transitory computer readable medium of P14, wherein the surface is a surface of the master component.

P16. The non-transitory computer readable medium of any of P14-P15, wherein casting the shadow of the cross section of the dependent component on a surface comprises:
creating an intermediate shadow of the cross section of the dependent component onto a two-dimensional shadow plane, said shadow plane parallel to a tangent plane tangent to the master surface at the point of intersection on the master surface where the dependent component intersects the master surface, the shadow having an outer edge and defining a contour at its outer edge, said contour being a curve of intersection between the master component and the dependent component;
selecting intermediate points on the curve of intersection; and
translating said intermediate points to the master surface to produce the first group of master surface points.

P17. The non-transitory computer readable medium of P16, wherein the tangent plane is co-planar with the shadow plane

P18. The non-transitory computer readable medium of P16, wherein the master surface comprises a flat surface defining a two-dimensional plane, and wherein said flat surface comprises the two-dimensional shadow plane.

P19. The non-transitory computer readable medium of any of P14-P18, wherein the surface is the master surface and the master surface comprises a curved surface at the point of intersection, and the two-dimensional shadow plane comprises a floating surface disposed between the dependent component and the master component, the floating surface normal to a line that is normal to the master surface at the point of intersection.

P20. The non-transitory computer readable medium of any of P14-P19, wherein the shadow is cast by parallel light rays.

P30. A non-transitory computer readable medium having computer-executable code stored thereon, the computer-executable code, when executed by a computer processor, executing a method, the method comprising the method of any of P1-P8.

Various embodiments of this disclosure may be implemented at least in part in any conventional computer programming language. For example, some embodiments may be implemented in a procedural programming language (e.g., “C”), or in an object-oriented programming language (e.g., “C++”), or in Python, R, Java, LISP or Prolog. Other embodiments of this disclosure may be implemented as preprogrammed hardware elements (e.g., application specific integrated circuits, FPGAs, and digital signal processors), or other related components.

In an alternative embodiment, the disclosed apparatus and methods may be implemented as a computer program product for use with a computer system. Such implementation may include a series of computer instructions fixed either on a tangible medium, such as a non-transitory computer readable medium (e.g., a diskette, CD-ROM, ROM, FLASH memory, or fixed disk). The series of computer instructions can embody all or part of the functionality previously described herein with respect to the system.

Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies.

Among other ways, such a computer program product may be distributed as a removable medium with accompanying printed or electronic documentation (e.g., shrink wrapped software), preloaded with a computer system (e.g., on system ROM or fixed disk), or distributed from a server or electronic bulletin board over the network (e.g., the Internet or World Wide Web). Of course, some embodiments of this disclosure may be implemented as a combination of both software (e.g., a computer program product) and hardware. Still other embodiments of this disclosure are implemented as entirely hardware, or entirely software.

Computer program logic implementing all or part of the functionality previously described herein may be executed at different times on a single processor (e.g., concurrently) or may be executed at the same or different times on multiple processors and may run under a single operating system process/thread or under different operating system processes/threads. Thus, the term “computer process” refers generally to the execution of a set of computer program instructions regardless of whether different computer processes are executed on the same or different processors and regardless of whether different computer processes run under the same operating system process/thread or different operating system processes/threads.

The embodiments of the invention described above are intended to be merely exemplary; numerous variations and modifications will be apparent to those skilled in the art. Such variations and modifications are intended to be within the scope of the present invention as defined by any of the appended claims.

What is claimed is:

1. A method for finite element analysis, in a computer, of a digital model of an interface between a master component and a dependent component of a physical apparatus, the method comprising:
obtaining a first digital model of the master component, the master component having a master surface;
obtaining a second digital model of the dependent component, the dependent component having a longitudinal axis and a cross section defining a connecting plane;
orienting the second digital model relative to the first digital model such that the longitudinal axis of the dependent component intersects a point of intersection on the first digital model;
casting a shadow of the cross section of the dependent component on a surface where the dependent component intersects the surface, the shadow defining a contour at its outer edge, said contour being a curve of intersection between the master component and the dependent component;
identifying a first group of master surface points on the surface of the master component, said first group of master surface points comprising a plurality of points forming the contour of the shadow on the surface of the master component;
identifying a second group of master surface points on the surface of the master component, said second group of master surface points comprising a plurality of points surrounding the first group of points;
defining a mesh comprising a plurality of mesh elements, each mesh element defined by a set of points from the first group of master surface points and the second group of master surface points; and
submitting the mesh to a finite element analysis system and performing finite element analysis of the mesh.

2. The method of claim 1, wherein the surface is a surface of the master component.

3. The method of claim 1, wherein casting a shadow of the cross section of the dependent component on a surface comprises:
creating an intermediate shadow of the cross section of the dependent component onto a two-dimensional shadow plane, said shadow plane parallel to a tangent plane tangent to the master surface at the point of intersection on the master surface where the dependent component intersects the master surface, the shadow having an outer edge and defining a contour at its outer edge, said contour being a curve of intersection between the shadow plane and the dependent component;
selecting intermediate points on the curve of intersection; and
translating said intermediate points to the master surface to produce the first group of master surface points.

4. The method of claim 3, wherein the shadow plane is co-planar with the tangent plane.

5. The method of claim 3, wherein the master surface comprises a flat surface defining a two-dimensional plane, and wherein said flat surface comprises the two-dimensional shadow plane.

6. The method of claim 3, wherein the surface is the master surface and the master surface comprises a curved surface at the point of intersection, and the two-dimensional shadow plane comprises a floating surface disposed between the dependent component and the master component, the floating surface normal to a line that is normal to the master surface at the point of intersection.

7. The method of claim 1, wherein the second group of points is radially outward of the first group of points, relative to the point of intersection, and each mesh element of the plurality of mesh elements has an aspect ratio of less than or equal to 4:1.

8. The method of claim 1, wherein the shadow is cast by parallel light rays.

9. A system for finite element analysis of a digital model of an interface between a master component specified by a first digital model and a dependent component specified by a second digital model, the dependent component having a longitudinal axis and a cross section defining a connecting plane, the system comprising:
a CAD module configured to provide the first digital model and the second digital model;
an orientation module configured for orienting the second digital model relative to the first digital model such that the longitudinal axis of the dependent component intersects a point of intersection on the first digital model;
a shadow module configured for casting a shadow of the cross section of the dependent component on a surface where the dependent component intersects the surface, the shadow defining a contour at its outer edge, said contour being a curve of intersection between the master component and the dependent component;
a points module configured for identifying a first group of master surface points on the surface of the master component, said first group of master surface points comprising a plurality of points forming the contour of the shadow on the surface of the master component;
the points module also configured for identifying a second group of master surface points on the surface of the master component, said second group of master surface points comprising a plurality of points surrounding the first group of points;
a mesh module configured for defining a mesh comprising a plurality of mesh elements, each mesh element defined by a set of points from the first group of master surface points and the second group of master surface points; and
a finite element analysis module configured for submitting the mesh to a finite element analysis system and performing finite element analysis of the mesh.

10. The system of claim 9, wherein the surface is a surface of the master component, and the shadow module configured for casting the shadow of the cross section of the dependent component on a surface of the master component.

11. The system of claim 9, wherein the system further comprises:
the CAD module is further configured to provide a two-dimensional shadow plane parallel to a tangent plane tangent to the master surface at the point of intersection on the master surface where the dependent component intersects the master surface, and
the shadow module is configured for creating an intermediate shadow of the cross section of the dependent component onto a shadow plane, the intermediate shadow having an outer edge and defining a contour at its outer edge, said contour being a curve of intersection between the master component and the dependent component;
the points module is configured for selecting intermediate points on the curve of intersection; and
translating said intermediate points to the master surface to produce the first group of master surface points.

12. The system of claim 11, wherein the tangent plane is co-planar with the tangent plane.

13. The system of claim 11, wherein the surface is a master surface of the master component, and the master surface comprises a curved surface at the point of intersection, and the two-dimensional shadow plane comprises a floating surface disposed between the dependent component and the master component, the floating surface normal to a line that is normal to the master surface at the point of intersection.

14. A non-transitory computer readable medium having computer-executable code stored thereon, the computer-executable code, when executed by a computer processor, executing a method, the method comprising:
providing a first digital model of the master component, the master component having a master surface;
providing a second digital model of the dependent component, the dependent component having a longitudinal axis and a cross section defining a connecting plane;
orienting the second digital model relative to the first digital model such that the longitudinal axis of the dependent component intersects a point of intersection on the first digital model;
casting a shadow of the cross section of the dependent component on a surface where the dependent component intersects the surface, the shadow defining a contour at its outer edge, said contour being a curve of intersection between the master component and the dependent component;
identifying a first group of master surface points on the surface of the master component, said first group of master surface points comprising a plurality of points forming the contour of the shadow on the surface of the master component;
identifying a second group of master surface points on the surface of the master component, said second group of master surface points comprising a plurality of points surrounding the first group of points;
defining a mesh comprising a plurality of mesh elements, each mesh element defined by a set of points from the first group of master surface points and the second group of master surface points; and
submitting the mesh to a finite element analysis system and performing finite element analysis of the mesh.

15. The non-transitory computer readable medium of claim 14, wherein the surface is a surface of the master component.

16. The non-transitory computer readable medium of claim 14, wherein casting the shadow of the cross section of the dependent component on a surface comprises:
creating an intermediate shadow of the cross section of the dependent component onto a two-dimensional shadow plane, said shadow plane parallel to a tangent plane tangent to the master surface at the point of intersection on the master surface where the dependent component intersects the master surface, the shadow having an outer edge and defining a contour at its outer edge, said contour being a curve of intersection between the master component and the dependent component;
selecting intermediate points on the curve of intersection; and
translating said intermediate points to the master surface to produce the first group of master surface points.

17. The non-transitory computer readable medium of claim 16, wherein the tangent plane is co-planar with the shadow plane

18. The non-transitory computer readable medium of claim 16, wherein the master surface comprises a flat surface defining a two-dimensional plane, and wherein said flat surface comprises the two-dimensional shadow plane.

19. The non-transitory computer readable medium of claim 14, wherein the surface is the master surface and the master surface comprises a curved surface at the point of intersection, and the two-dimensional shadow plane comprises a floating surface disposed between the dependent component and the master component, the floating surface normal to a line that is normal to the master surface at the point of intersection.

20. The non-transitory computer readable medium of claim 14, wherein the shadow is cast by parallel light rays.
